(19) United States
(12) Patent Application Publication
(10) Pub. No.: US 2012/0147533 A1
(43) Pub. Date: Jun. 14, 2012

(54) ELECTRONIC DEVICE WITH MULTI-ORIENTATION

(75) Inventors: CHIA-MIN WANG, Tu-Cheng (TW); ZHI-GANG YANG, Shenzhen City (CN); HUI YUAN, Shenzhen City (CN); PING YU, Shenzhen City (CN)

(73) Assignees: HON HAI PRECISION INDUSTRY CO., LTD., Tu-Cheng (TW); HONG FU JIN PRECISION INDUSTRY (ShenZhen) CO. LTD., Shenzhen City (CN)

(21) Appl. No.: 13/158,464

(22) Filed: Jun. 13, 2011

(30) Foreign Application Priority Data
Dec. 10, 2010 (CN) 201010582794.9

(51) Int. Cl. H05K 7/00

(52) U.S. Cl. 361/679.01

(57) ABSTRACT

An electronic device includes a back shell and a support. One of the back shell or the support is formed with a number of pairs of holes arranged in a number of parallel lines. The other one of the back shell or the support is formed with a pair of positioning posts. The positioning posts are received in any pair of the holes to position the support, thereby supporting the back shell in different orientations.

### BACKGROUND

1. Technical Field

The present disclosure relates to electronic devices with a support, especially to an electronic device with a multi-orientation support.

2. Description of Related Art

Portable electronic devices such as digital photo frames usually include a support to support the digital photo frame on a table. The support can only support the digital photo frame in one or two orientations. It is appreciated and useful if a support can provide more orientations for the portable electronic devices.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an isometric view of an electronic device according to an exemplary embodiment.

FIG. 2 is similar to FIG. 1, but with the support separated from the back shell in FIG. 1.

FIG. 3 is an exploded view of the electronic device of FIG. 1.

FIG. 4 is similar to FIG. 2, but viewed from a different viewpoint.

### DETAILED DESCRIPTION

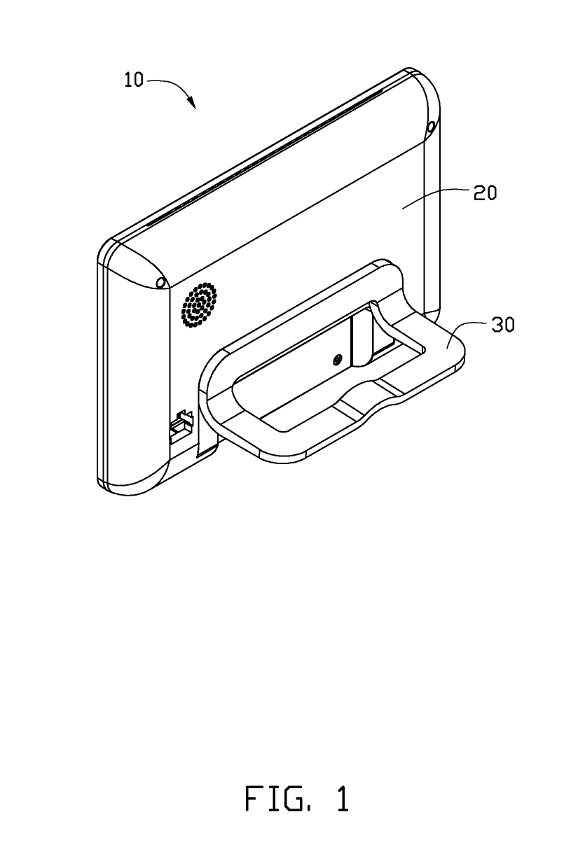

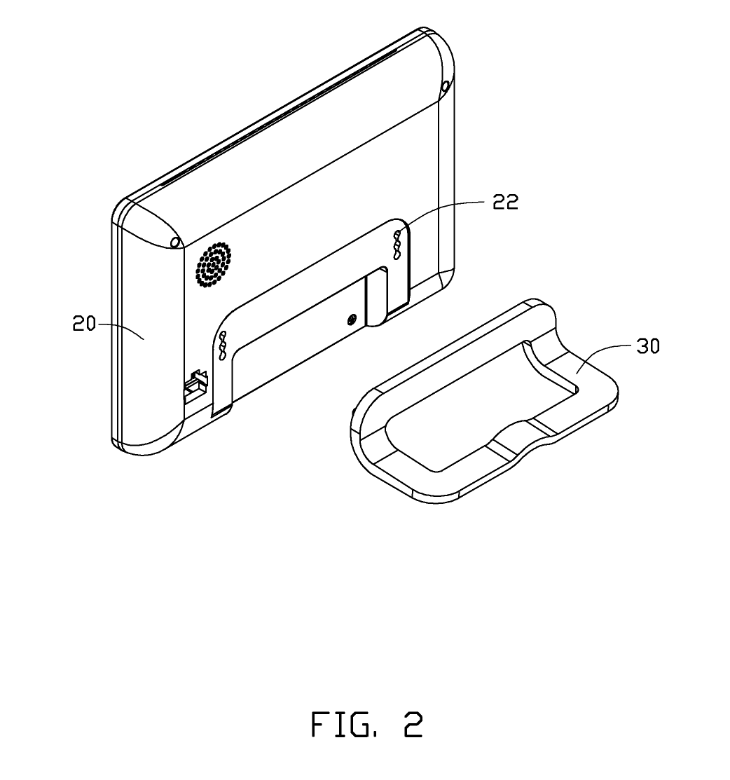

Referring to FIGS. 1 and 2, an electronic device 10 according to an exemplary embodiment includes a back shell 20 of a body (not shown) and a support 30 fixed to the back shell 20. The back shell 20 is formed with a number of pairs of holes 22. The holes 22 are arranged in two parallel lines. In the exemplary embodiment, there are three pairs of holes 22. The support 20 can be positioned in any pair of the holes 22, thereby supporting the body in different orientations.

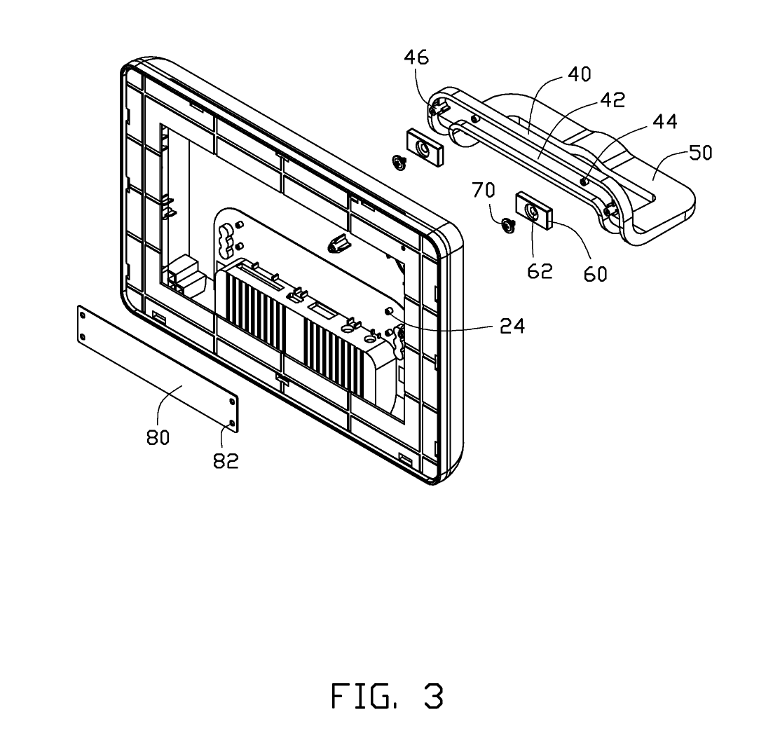

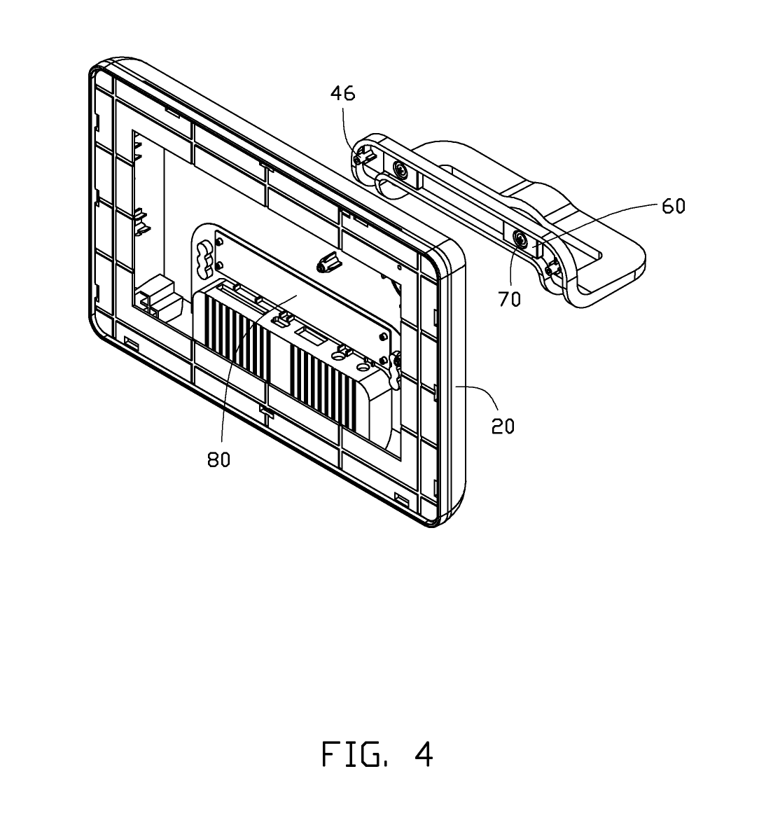

Referring to FIGS. 3 and 4, the support 30 includes a connecting portion 40 and a support portion 50. The connecting portion 40 is detachably connected to the back shell 20. The support portion 50 is obliquely fixed to the connecting portion 40. A number of magnets 60 are fixed to the inside of the connecting portion 40. The connecting portion 40 defines a groove 42 in its inner side. The magnets 60 are received in the groove 42. Two positioning posts 46 and a number of fixing posts 44 protrude from the bottom of the groove 42.

Referring again to FIG. 2, the two positioning posts 46 can be inserted into any pair of holes 22. The support 30 can then position in different positions with respect to the back shell 20, and can support the body of the electronic device 10 in different orientations. Each fixing post 44 defines a threaded hole (not labeled). Each magnet 60 defines a through hole 62. The magnets 60 are fixed to the connecting portion 40 by a number of bolts 70 passing through the through holes 62 that are screwed into the threaded holes.

A metal plate 80 is fixed to the inner side of back shell 20. The metal plate 80 defines a number of through holes 82. The back shell 20 includes a number of protruding posts 24, formed with a threaded hole (not labeled), in its inner side. The metal plate 80 is fixed to the back shell 20 by a number of bolts (not shown) passing through the through holes 82 and screwed into the threaded holes of the protruding posts 24. When the positioning posts 46 are received in the holes 22, the support 30 is fixed to the back shell 20 via the attraction between the metal plate 80 and the magnet 60. In an alternative embodiment, the support 30 can be fixed to the back shell 20 by any suitable connection techniques.

In an alternative exemplary embodiment, the metal plate 80 may be fixed to the connecting portion 40, and the magnets 60 may be fixed to the back shell 20.

It is to be understood, however, that even though numerous characteristics and advantages of the present disclosure have been set forth in the foregoing description, together with details of the structure and function of the present disclosure, the present disclosure is illustrative only, and changes may be made in detail, especially in matters of shape, size, and arrangement of parts within the principles of the present disclosure to the full extent indicated by the broad general meaning of the terms in which the appended claims are expressed.

What is claimed is:

1. An electronic device comprising:
a back shell; and
a support;
wherein one of the back shell or the support is formed with a plurality of pairs of holes arranged in a plurality of parallel lines, with each pair arrange in one of the parallel lines, and the other one of the back shell or the support is formed with a pair of positioning posts, the positioning posts are capable of being received in any pair of the holes to position the support, thereby supporting the back shell in different orientations.

2. The electronic device of claim 1, wherein the pairs of holes are formed in the back shell, and the positioning posts are formed on the support.

3. The electronic device of claim 2, wherein the support comprises a connecting portion, at least one magnet is fixed to the connecting portion, a metal plate opposite to the connecting portion is fixed to the back shell, the connecting portion is connected to the back shell by the attraction between the at least one magnet and the metal plate.

4. The electronic device of claim 2, wherein the support comprises a connecting portion, a metal plate is fixed to the connecting portion, at least one magnet opposite to the connecting portion is fixed to the back shell, the connecting portion is connected to the back shell by the attraction between the at least one magnet and the metal plate.

5. The electronic device of claim 2, wherein the number of the pairs of the holes is three.
